(19) United States
(12) Patent Application Publication
(10) Pub. No.: US 2022/0154339 A1
(43) Pub. Date: May 19, 2022

(54) THIN FILM DEPOSITION APPARATUS MOUNTABLE WITH ANALYSIS SYSTEM

(71) Applicant: KOREA INSTITUTE OF SCIENCE AND TECHNOLOGY, Seoul (KR)

(72) Inventors: In Soo KIM, Seoul (KR); Chun Keun KIM, Seoul (KR); KWAN IL LEE, Seoul (KR); Gumin KANG, Seoul (KR); Joon Hyun KANG, Seoul (KR); Jin Gu KANG, Seoul (KR); Wonsuk LEE, Seoul (KR)

(73) Assignee: KOREA INSTITUTE OF SCIENCE AND TECHNOLOGY, Seoul (KR)

(21) Appl. No.: 16/952,530

(22) Filed: Nov. 19, 2020

(51) Int. Cl. C23C 16/52; C23C 16/455; G01N 21/65; C23C 16/44; G01J 3/44; G01J 3/02

(52) U.S. Cl. CPC C23C 16/52; C23C 16/45544; C23C 16/45536; G01N 21/65; C23C 16/40; G01J 3/4412; G01J 3/0291; G01J 3/0205; C23C 16/4409

(57) ABSTRACT

A thin film deposition apparatus mounted with a Raman analysis system is discussed. The thin film deposition apparatus includes a reaction chamber providing an inner space for forming a thin film. An opening is formed on the thin film deposition apparatus to be connected to the reaction chamber, and the opening is closed by a window through which light can be transmitted.

### BACKGROUND

### Technical Field

The present disclosure relates to a thin film deposition apparatus, and more particularly, to a thin film deposition apparatus mountable with an analysis system.

### Background Art

Thin film forming process can be used in various processes including semiconductor processes and can also be used in a process for manufacturing an optoelectronic device, for example. Examples of the thin film forming process include an atomic layer deposition (ALD), a chemical vapor deposition (CVD), sputtering deposition, an aerosol process, a sol-gel method, a spin coating method, and the like. Among them, the atomic layer deposition is utilized to form a thin film having one or more of atomic layers.

According to the atomic layer deposition, precursors, reactants, and the like, for example, are introduced into the reaction chamber, and then a thin film having one or more of atomic layers can be formed by the self-limiting surface reaction.

When the self-limiting surface reaction is used, the reaction terminates by itself when the functional groups of the material introduced into the reaction chamber are completely depleted. For example, when the functional groups of the metal source introduced into the reaction chamber are completely depleted by the oxygen source, the reaction does not proceed even when the oxygen source is additionally introduced. When the functional groups of the oxygen source are completely depleted by the metal source, the reaction does not proceed even when the metal source is additionally introduced. Likewise, the same applies to when sulfur source or nitrogen source is used instead of oxygen source, which can be used to synthesize a thin film containing metal sulfides or metal nitrides.

The atomic layer deposition can realize excellent conformality, uniformity, precise thickness control, and the like, using such self-limiting thin film growth mechanism.

ALD or CVD process is mainly used for forming the atomic layers of 2-dimensional materials (e.g., MoS₂, WS₂, etc.). The properties of 2-dimensional materials can vary as the thickness changes. Accordingly, the thickness of 2-dimensional materials should be analyzed in the process of forming the atomic layers in real time. However, there is no practical way of analyzing the thickness during ALD or CVD process in real time.

### SUMMARY

The present disclosure has been made to solve the problems mentioned above, and it is an object of the present disclosure to provide a thin film deposition apparatus mountable with an analysis system outside a reaction chamber.

It is an object of the present disclosure to provide a thin film deposition apparatus mountable with an analysis system outside a reaction chamber using an opening of the thin film deposition apparatus.

It is an object of the present disclosure to provide an atomic layer deposition apparatus mounted with an analysis system outside a reaction chamber, in which the analysis system can analyze in situ film formation occurring inside the reaction chamber.

According to an embodiment of the present disclosure, it is possible to mount an analysis system outside a reaction chamber, in which the analysis system can analyze in situ film formation occurring inside the reaction chamber.

According to an embodiment of the present disclosure, it is possible to analyze a thin film layer in situ using a Raman Spectroscopy analysis system mounted outside the reaction chamber.

According to an embodiment of the present disclosure, since the analysis system can be mounted outside the reaction chamber, it is possible to mount the analysis system on the thin film deposition apparatus without requiring excessive changes in the structure of the deposition apparatus in use, thus allowing a maximum utilization of the existing process facility infrastructure.

According to an embodiment of the present disclosure, since the analysis system can be mounted outside the reaction chamber, it is possible to minimize unnecessary influence on the process conditions inside the reaction chamber when the analysis system is mounted.

The effects of the present disclosure are not limited to those mentioned above, and other objects that are not mentioned above can be clearly understood to those skilled in the art from the claims.

### BRIEF DESCRIPTION OF THE DRAWINGS

The above and other objects, features and advantages of the present disclosure will become more apparent to those of ordinary skill in the art by describing in detail exemplary embodiments thereof with reference to the accompanying drawings, in which:

FIG. 1 is a cross-sectional view showing a cross-sectional structure of an atomic layer deposition apparatus according to an embodiment of the present disclosure;

FIG. 2 is a plan view showing an upper surface of the atomic layer deposition apparatus according to an embodiment of the present disclosure; and

FIG. 3 is a cross-sectional view showing the cross-sectional structure of the atomic layer deposition apparatus mounted with an analysis system according to an embodiment of the present disclosure.

### DETAILED DESCRIPTION OF THE EMBODIMENTS

Throughout the description, the term “rays,” “electromagnetic wave,” or “light” includes radio waves, infrared rays, visible rays, ultraviolet rays, X rays, and the like, and is not limited to specifying electromagnetic waves of a specific wavelength.

Throughout the description, “thin film deposition apparatus” is used in the sense encompassing all of the deposition apparatuses for forming a thin film using ALD, CVD (chemical vapor deposition), a physical vapor deposition (PVD), or a sputtering method, and the like.

Throughout the description, “precursor” can mean a precursor or a reactant used in the atomic layer deposition process, and is not limited to a specific substance.

As used throughout the description, the term “layer” refers to a form of a layer having with a thickness. The layer can be porous or non-porous. By “(being) porous,” it means having a porosity. The layer can have a bulk form or can be a single crystal thin film.

Throughout the description, when it is described that a certain member is positioned “on” another member, unless specifically stated otherwise, it includes not only when the certain member is in contact with another member, but also when the two members are intervened with yet another member that can be present therebetween.

As used throughout the description, the term “gas” state refers to the gas state as well as the plasma state.

As used throughout the description, the terms “about,” “substantially” are meant to encompass tolerances.

As used throughout the description, the expression “A and/or B” refers to “A, or B, or A and B.”

Throughout the description, when a portion is stated as being “connected” to another portion, it encompasses not only when the portions are “directly connected,” but also when the portions are “electrically connected” while being intervened by another element present therebetween.

Hereinafter, preferred embodiments of the present disclosure will be described in detail with reference to the accompanying drawings so that those with ordinary knowledge in the art can easily achieve the present disclosure. However, the description proposed herein is just an embodiment for the purpose of illustrations only, not intended to limit the scope of the disclosure, so it should be understood that other equivalents and modifications could be made thereto without departing from the scope of the disclosure. In the following description, the functions or elements irrelevant to the present disclosure will not be described for the sake of clarity, and the like reference numerals are used to denote the same or similar elements in the description and drawings.

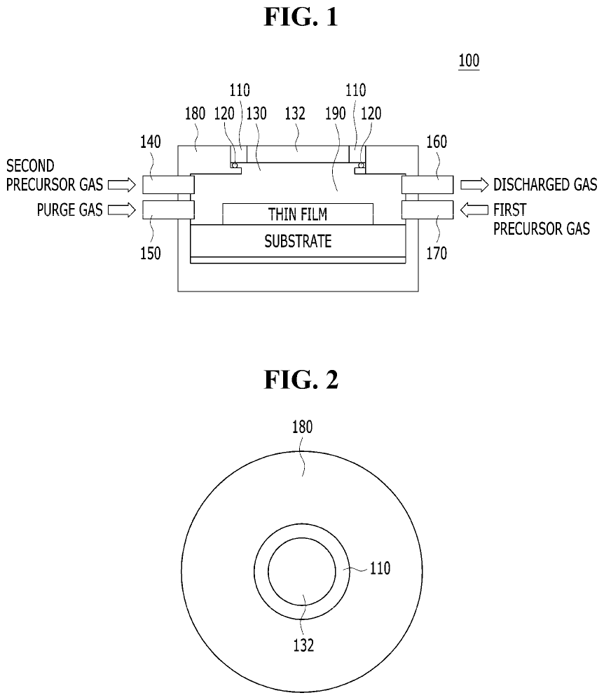

FIG. 1 is a cross-sectional view showing a cross-sectional structure of an atomic layer deposition apparatus 100 according to an embodiment of the present disclosure.

The atomic layer deposition apparatus 100 can include a reaction chamber 190, and the reaction chamber 190 provides an inner space for forming a thin film having one or more of atomic layers. The atomic layer deposition apparatus 100 is illustrated as having a cylindrical shape, but is not limited thereto, and can have various shapes.

The atomic layer deposition process for forming the thin film having one or more of atomic layers corresponds to a nano-scale thin film deposition technology using chemical adsorption and desorption of a monoatomic layer.

The atomic layer deposition process can be performed in a cycle manner, for example, and can have four steps. In the first step, a first precursor is supplied, and in the second step, a purge gas is supplied and discharged to remove the excess first precursor and by-products. In the third step, a second precursor is supplied, and in the fourth step, a purge gas is supplied and discharged to remove the excess second precursor and by-products. These are the four steps of the basic cycle for thin film growth and can be repeated to control the thickness of the thin film. The time required for one basic cycle can vary depending on the purpose of the process, the chemical properties of the precursor, the structure of the substrate on which the thin film is formed, the deposition temperature, the reactivity between the substrate and the precursor, and the like. The time required for the basic cycle can be precisely controlled by monitoring in-situ the thin film formation through an analysis system according to the present disclosure.

The atomic layer deposition apparatus 100 includes precursor gas supply units 140 and 170 that supply precursor gas to the inside of the atomic layer deposition apparatus 100. Although two precursor gas supply units 140 and 170 are illustrated in FIG. 1, the present disclosure is not limited thereto, and the number of precursor gas supply units 140 and 170 can be changed according to a composition required to form a thin film.

The atomic layer deposition apparatus 100 includes a purge gas supply unit 150 for supplying a purge gas to the inside of the atomic layer deposition apparatus 100. Although one purge gas supply unit 150 is illustrated in FIG. 1, the present disclosure is not limited thereto, and the number of purge gas supply units can be changed according to the thin film forming process.

The atomic layer deposition process includes a time division atomic layer deposition process, a spatial division atomic layer deposition process, a thermal atomic layer deposition process, a plasma deposition process, an ozone (O₃)-based atomic layer deposition process, and the like, and the position and the number of the precursor gas supply units 140 and 170 and the purge gas supply unit 150 can be modified according to each process. In addition, the gas provided through the precursor gas supply units 140 and 170 and/or the purge gas supply unit 150 can be in a gas state or a plasma state.

Although the atomic layer deposition apparatus 100 shown in FIG. 1 is illustrated as including one reaction chamber 190, the present disclosure is not limited thereto, and the internal structure of the atomic layer deposition apparatus 100 can be modified according to the atomic layer deposition process.

The thin film on the substrate shown in FIG. 1 is a thin film formed through the atomic layer deposition process, and can correspond to a thin film of various materials such as oxide, nitride, sulfide, metal, halide perovskite, and the like.

For example, the cycle used in the atomic layer deposition process for depositing an alumina thin film on a substrate in the reaction chamber 190 includes: (1) supply of an aluminum precursor through the first precursor gas supply unit 170, (2) supply of an inert gas or purge gas (e.g., N₂) through the purge gas supply unit 150, and discharge of residue through an exhaust unit 160, (3) supply of oxidizing agent (second precursor gas supply unit 140 can be used as an oxidizing agent supply unit), and (4) supply of inert gas or purge gas (e.g., N₂) through the purge gas supply unit 150 and discharge of residue through the exhaust unit 160. After aluminum precursor and oxidizing agent are supplied to be absorbed on the substrate surface, the residues (e.g., aluminum precursor and oxidizing agent) not participating in the reaction are removed from the substrate surface and discharged by the purge gas. The film formation is completed through this process.

For example, an alumina thin film is deposited using trimethylaluminum (TMA)/H₂O as the aluminum precursor. In the atomic layer deposition process, TMA is used as a precursor for metal compounds, and H₂O acts as an oxygen reactant. The metal oxide is deposited during the atomic layer deposition process. The deposited thin film is exposed to H₂O, and the hydroxyl group remains on the surface of the thin film. The hydroxyl group reacts with the metal compound precursor. The residues (e.g., aluminum precursor and oxidizing agent) not participating in the reaction are removed from the substrate surface and discharged by the purge gas. The film formation is completed through repetition of this process.

The exemplary thin film can include transition metal dichalcogenides (MoS₂, WS₂, VS₂, etc.).

FIG. 2 is a plan view showing an upper surface of the atomic layer deposition apparatus 100 according to an embodiment of the present disclosure.

An opening 130 connected to the reaction chamber 190 is formed on the atomic layer deposition apparatus 100. According to an embodiment of the present disclosure, the opening 130 can be formed on the upper surface 180 of the atomic layer deposition apparatus 100. The opening 130 can be closed by a window 132 through which light or electromagnetic waves can be transmitted. Additionally, a window mount 110 and an O-ring 120 can be provided (see FIG. 1).

According to an embodiment of the present disclosure, an O-ring 120 can be provided under the window mount 110 to ensure that the inner space of the reaction chamber 190 is securely maintained in a vacuum state (or in a state filled with purge gas). The O-ring 120 tightly close a gap between a circumference of the opening 130 and a circumference of the window mount 110. Various members for maintaining the state of the inner space of the reaction chamber 190 can be used in place of the O-ring 120 or in addition to the O-ring 120.

The window 132 can close the opening 130 to maintain the internal state of the reaction chamber 190, and light or electromagnetic waves can be transmitted through the window 132. According to an embodiment of the present disclosure, visible rays emitted from the in-situ Raman spectroscopy analysis system can pass through the window 132. The visible rays can pass through the window 132 to a specific location inside the reaction chamber 190, for example, to a location where a thin film is formed. The visible rays backscattered (Raman scattering) by the thin film can pass through the window 132 again and be emitted to the outside of the reaction chamber 190. The backscattered visible rays passed through the collimator is dispersed onto a detector. The in-situ Raman analysis system can compare the energy difference between the scattered visible rays and the incident energy, thus analyzing in real time vibrational modes of materials which, in turn, corresponds to the thickness or the crystalline structure in the process of forming the thin film.

In the example described above, although visible rays have been described as an example, the present disclosure is not limited thereto, and the film formation can be analyzed using electromagnetic waves having a wavelength other than visible rays.

The window 132 can be formed of a material through which electromagnetic waves can pass. According to an embodiment of the present disclosure, the window 132 can be formed of a material through which electromagnetic waves having wavelengths of visible rays can pass. According to another embodiment of the present disclosure, the window 132 can be formed of a material through which electromagnetic waves having wavelengths other than visible rays can pass. When visible rays are used as the measurement wavelength, it is possible to measure reflectance, refractive index, and the like of the thin film. According to an embodiment of the present disclosure, the window 132 can be an aspheric lens.

As an example, the window 132 can be formed by using SiO₂. Alternatively, the window 132 can be formed by using any one of Si, AgBr, AgCl, Al₂O₃, BaF₂, CaF₂, CdTe, Csl, GaAs, Ge, Irtran-2, KBr, KRS-5, LiF, MgF₂, NaCl, ZnS, ZnSe, and sapphire, or a combination thereof. According to an embodiment of the present disclosure, the window 132 can be formed by using Si.

According to an embodiment of the present disclosure, the inner space of the reaction chamber 190 can be maintained in a vacuum or filled with inert gas such as nitrogen gas (N₂). In addition, the inner space of the reaction chamber 190 can be filled with dry air.

According to an embodiment of the present disclosure, a thin film is formed on the substrate, and the substrate can be a silicon substrate.

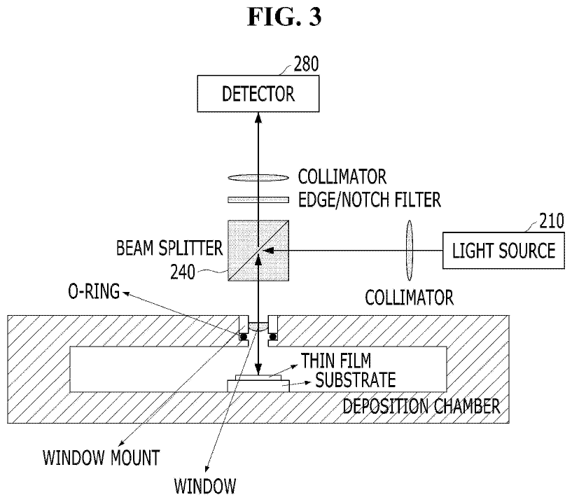

FIG. 3 is a cross-sectional view showing the cross-sectional structure of the atomic layer deposition apparatus 100 mounted with an analysis system according to an embodiment of the present disclosure.

The analysis system includes a light source 210, a light splitter 240, and a light detector 280. Additionally, a collimator, an edge filter, and a notch filter can be provided.

According to an embodiment of the present disclosure, the analysis system corresponds to an in-situ Raman spectroscopy analysis system. By using the in-situ Raman spectroscopy analysis, it is possible to perform in-situ analysis on the thickness or the crystalline structure of the thin film in the inner space of the reaction chamber 190. The spectroscopy technique is used for the in-situ analysis. A portion of the visible rays emitted from the light source 210 is absorbed by the thin film, and the rest thereof reaches the light detector 280 to be measured. The spectrums can be plotted as a function of frequency by comparing the rays detected by the light detector 280 with the rays emitted from the light source 210. Accordingly, the thickness or the crystalline structure of the thin film can be analyzed by the Raman spectrometer.

In the example described above, although visible rays have been described as an example, the present disclosure is not limited thereto, and the film formation can be analyzed with spectroscopy using electromagnetic waves having wavelengths other than visible rays. For example, when visible rays are used, it is possible to measure reflectance, refractive index, and the like of the thin film.

The light source 210 can emit light or electromagnetic waves. According to an embodiment of the present disclosure, the light source 210 emits the light to the light (beam) splitter 240.

The light splitter 240 can deflect the incident light by 90 degrees to the window 132 toward the thin film in the inner space of the reaction chamber 190. Further, the light splitter 240 can transmit the light scattered from the thin film to an edge filter or a notch filter.

The filter can filter the light scattered from the thin film and pass only inelastically scattered beam. The inelastically scattered beam can pass through a collimator so as to reach the detector 280.

According to an embodiment of the present disclosure, the light detector 280 can use the Raman spectroscopy analysis system. That is, the light detector 280 can convert the spectrum of the received light as a function of frequency, and the spectroscopic analysis of the thin film can be performed based on the result. By using the Raman spectroscopy analysis system, it is possible to track in situ the film formation occurring in the process of forming a thin film.

According to an embodiment of the present disclosure, by performing Raman spectroscopy analysis on the light incident on the thin film, it is possible to analyze the thickness and the crystalline structure, and to determine the optimum process conditions such as the reaction temperature of the atomic layer and the amount of precursors, and so on. The film formation, which could not be analyzed with the existing apparatuses, can be tracked in situ, and the processing conditions can be optimized.

As described above, the analysis system can be positioned outside the reaction chamber 190 using the opening 130, the window 132. Accordingly, without substantially changing the structure of the atomic layer deposition apparatus 100, the analysis system can be easily mounted to analyze in situ a thin film formation process in the inner space of the reaction chamber 190. In particular, by mounting the in-situ Raman analysis system outside the reaction chamber, information on the thickness or the crystalline structure in progress in the reaction chamber 190 can be provided in real-time, thus resulting in real-time analysis of the thin film layer.

Although the above description was mainly focused on the atomic layer deposition apparatus (ALD) 100, the present disclosure is not limited thereto, and can be applicable to an apparatus for depositing a thin film using various methods. The configuration described above can also be applicable to a thin film deposition apparatus using the reaction chamber 190, such as a chemical vapor deposition (CVD) apparatus or a physical vapor deposition (PVD) apparatus.

The previous description of the disclosure is provided to enable those skilled in the art to perform or use the disclosure. Various modifications of the disclosure will be readily apparent to those skilled in the art, and the generic principles defined herein can be applied to various modifications without departing from the spirit or scope of the disclosure. Thus, the present disclosure is not intended to be limited to the examples described herein but is intended to be accorded the broadest scope consistent with the principles and novel features disclosed herein.

While the present disclosure has been described in connection with some embodiments herein, it should be understood that various modifications and changes can be made without departing from the scope of the present disclosure as would be understood by those skilled in the art. Further, such modifications and changes are intended to fall within the scope of the claims appended herein.

What is claimed is:

1. A thin film deposition apparatus mounted with a Raman analysis system, the thin film deposition apparatus comprising:
a reaction chamber providing an inner space for forming a thin film;
a light source that emits light to be transmitted to the thin film;
a light detector that measures the light reflected from the inner space of the reaction chamber,
wherein an opening is formed on the thin film deposition apparatus to be connected to the reaction chamber, and
the opening is closed by a window through which the light can be transmitted.

2. The thin film deposition apparatus according to claim 1, wherein the light comprises electromagnetic waves having wavelengths of visible rays.

3. The thin film deposition apparatus according to claim 2, wherein the light detector compares visible rays emitted from the light source with visible rays detected at the light detector, to measure an amount of visible absorption of the thin film disposed in the inner space of the reaction chamber.

4. The thin film deposition apparatus according to claim 1, wherein the thin film deposition apparatus is a deposition apparatus for forming the thin film having one or more of atomic layers.

5. The thin film deposition apparatus according to claim 4, wherein the thin film comprises transition metal dichalcogenides or metal oxides.

6. The thin film deposition apparatus according to claim 1, wherein a substrate is disposed in the inner space of the reaction chamber, and the substrate is a silicon substrate.

7. The thin film deposition apparatus according to claim 1, further comprising a light splitter that deflects incident light toward the thin film.

8. The thin film deposition apparatus according to claim 7, further comprising a filter to which light scattered from the thin film is transmitted by the light splitter and through which the light scattered from the thin film is filtered to reach the light detector.

9. The thin film deposition apparatus according to claim 1, further comprising:
at least one precursor gas supply unit that supplies precursor gas therein.

10. The thin film deposition apparatus according to claim 1, wherein the window is an aspheric lens.

11. The thin film deposition apparatus according to claim 1, wherein an O-ring is provided under a window mount.
